(19) United States
(12) Patent Application Publication
(10) Pub. No.: US 2009/0162758 A1
(43) Pub. Date: Jun. 25, 2009

(54) PHOTOMASK HAVING CODE PATTERN FORMED BY CODING DATA CONVERSION PROCESS INFORMATION, PHOTOMASK FORMATION METHOD, AND SEMICONDUCTOR DEVICE FABRICATION METHOD

(76) Inventor: Osamu Ikenaga, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/338,550

(22) Filed: Dec. 18, 2008

(30) Foreign Application Priority Data
Dec. 20, 2007 (JP) 2007-329068

(51) Int. Cl. G03F 1/00; G06F 17/50; G03F 7/20

(52) U.S. Cl. 430/5; 716/19; 430/319

(57) ABSTRACT

Design data of a wafer pattern to be formed on a semiconductor wafer is converted into mask data corresponding to a mask pattern to be formed on a photomask for use in the formation of the wafer pattern, and the mask pattern is formed on the photomask on the basis of the mask data. A code pattern obtained by coding information of the data conversion process of converting the design data into the mask data is formed on the photomask.

### CROSS-REFERENCE TO RELATED APPLICATIONS

This application is based upon and claims the benefit of priority from prior Japanese Patent Application No. 2007-329068, filed Dec. 20, 2007, the entire contents of which are incorporated herein by reference.

### BACKGROUND OF THE INVENTION

1. Field of the Invention

The present invention relates to the fabrication of a semiconductor device and, more particularly, to a photomask capable of managing information representing a data formation procedure and process environment for forming a pattern on a photomask for use in a lithography step, a method of forming the photomask, and a semiconductor device fabrication method using the photomask.

2. Description of the Related Art

General steps of forming a photomask for use in a semiconductor device fabrication process will be briefly explained below. First, to form a desired pattern on a photomask, data processing following a predetermined procedure is performed on design data expressing the pattern of a semiconductor device, thereby performing data conversion from the design data to mask data. Then, on the basis of the mask data obtained by this processing, the desired pattern is written on the photomask by a charged beam or laser beam lithography apparatus. After that, the pattern written on the photomask is developed and etched into the desired pattern, thereby forming the desired pattern on the photomask. In this manner, the photomask having the desired pattern is formed.

In the step of converting the design data into the mask data described above, a predetermined correction process is performed so that the semiconductor device pattern expressed by the design data is formed on a semiconductor wafer with desired accuracy. A representative example of this correction process is data processing called OPC (Optical Proximity Correction). More specifically, the OPC process is to correct deformation that occurs on a pattern formed on a photomask when exposing the pattern to a semiconductor wafer by using a demagnification projecting exposure apparatus called an aligner. Examples of the pattern deformation that occurs when exposing a pattern formed on a photomask to a semiconductor wafer are a dimensional fluctuation caused by the influence of a target pattern periphery, and a thin pattern at the end portion of the pattern.

The process contents of the data processing represented by this OPC process are beginning to be extremely complicated as the processing pattern width on a semiconductor wafer decreases with respect to the exposure wavelength of the aligner. Also, to obtain a semiconductor device that achieves or satisfies desired performance, the semiconductor device must be developed by repeating processing cycles including the formation of a photomask performed by correcting not only design data but also the correction contents in the OPC process, and the exposure process and pattern processing performed on a semiconductor wafer. To develop a semiconductor device, it is important during the course of the development to manage documents pertaining to the correction log of the OPC process contents, the version management log of software for performing the OPC process, and the computer environment in which the process is performed. However, semiconductor device development using this dimension guaranteeing method has the following problems.

As disclosed in, e.g., Jpn. Pat. Appln. KOKAI Publication Nos. H05-313350 and 2001-13674, documents of various kinds of logs such as the design data, OPC procedure, and OPC process environment when making a photomask for use in the fabrication of a semiconductor device are managed in the form of electronic files. Unfortunately, management of associating these logs with the photomask as a product of the logs is becoming very cumbersome as the correction frequency of the above-mentioned design data and OPC process contents increases, or demands for shortening the TAT (Turn Around Time) required for the data processing increase. In addition, as the number of masks to be formed increases and the time required for the mask formation prolongs, the management amount of documents in the form of electronic files has become enormous. Consequently, infrastructures for storing and managing the various kinds of data and information and human resources for the management and operation are necessary. This makes it difficult to reduce the cost required to develop a semiconductor device.

### BRIEF SUMMARY OF THE INVENTION

A photomask formation method according to an aspect of the present invention comprising converting design data of a wafer pattern to be formed on a semiconductor wafer into mask data corresponding to a mask pattern to be formed on a photomask for use in the formation of the wafer pattern, and forming the mask pattern on the photomask on the basis of the mask data, and forming, on the photomask, a code pattern obtained by coding information of the data conversion process of converting the design data into the mask data.

A photomask according to another aspect of the present invention comprising a code pattern obtained by coding information of a data conversion process of converting design data of a wafer pattern to be formed on a semiconductor wafer into mask data corresponding to a mask pattern to be formed on a photomask for use in the formation of the wafer pattern.

A semiconductor device fabrication method according to still another aspect of the present invention comprising transferring a mask pattern onto a semiconductor wafer by using a photomask, and forming the wafer pattern on the semiconductor wafer on the basis of the transferred mask pattern, a method of forming the photomask including converting design data of a wafer pattern to be formed on a semiconductor wafer into mask data corresponding to a mask pattern to be formed on a photomask for use in the formation of the wafer pattern, and forming the mask pattern on the photomask on the basis of the mask data, and forming, on the photomask, a code pattern obtained by coding information of the data conversion process of converting the design data into the mask data.

### BRIEF DESCRIPTION OF THE SEVERAL VIEWS OF THE DRAWING

FIG. 1 is a schematic view for explaining photomask formation steps according to the first embodiment of the present invention, showing the procedure of making a photomask and the process contents performed in each step;

FIG. 2 is a view for explaining an example of the procedure of a CAD process in a photomask formation method according to the first embodiment of the present invention;

FIG. 3 is a view for explaining practical contents of the procedure of the CAD process shown in FIG. 2;

FIG. 4 is a graph showing an example of information for forming a correction model for correcting a wafer pattern for use in the photomask formation method according to the first embodiment of the present invention, i.e., showing the relationship between an adjacent pattern distance and finished dimensional value;

FIG. 5 is a plan view schematically showing patterns formed on a photomask by the photomask formation method according to the first embodiment of the present invention;

FIG. 6 is a view schematically showing a data structure included in the patterns on the photomask shown in FIG. 5; and

FIG. 7 is a view schematically showing an example of information expressed by a two-dimensional barcode pattern included in the patterns on the photomask shown in FIG. 5.

### DETAILED DESCRIPTION OF THE INVENTION

### First Embodiment

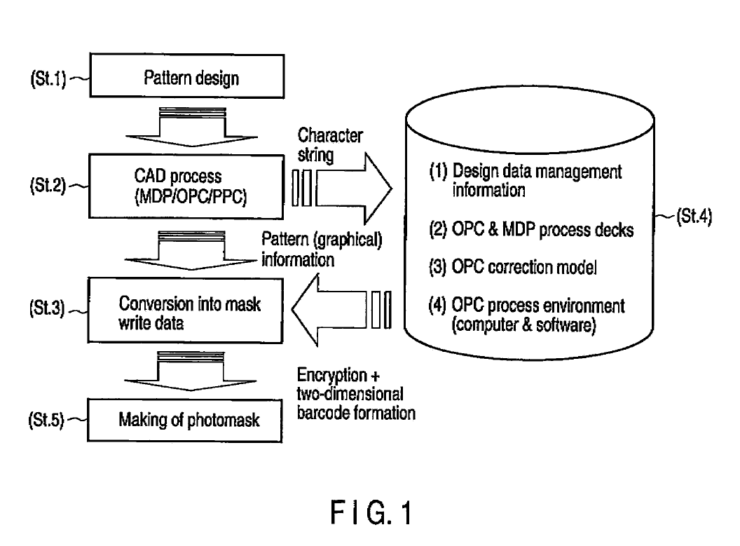

A photomask, photomask formation method, and semiconductor device fabrication method according to the first embodiment of the present invention will be explained below with reference to FIGS. 1 to 7.

FIG. 1 is a view for explaining photomask formation steps according to this embodiment, and schematically shows the procedure of making a photomask and the contents of processing performed in each step. First, a desired pattern for fabricating a semiconductor device is designed. More specifically, a desired wafer pattern to be formed on a semiconductor wafer for fabricating the semiconductor device is designed. In addition, design data expressing this wafer pattern is formed. This step is step 1 (St.1).

Then, predetermined processing is performed on the design data formed in step 1. More specifically, a CAD (Computer Aided Design) process is performed by a computer on the design data formed in step 1. This step is step 2 (St.2). The CAD process in step 2 includes various data conversion processes to be described below.

For example, an interlayer data calculation process is performed to generate, from the design data formed in step 1, mask pattern data expressing a mask pattern to be formed on a photomask for use in semiconductor device fabrication steps. This interlayer data calculation process includes, e.g., ANDing or ORing of the design data of the wafer pattern. The mask pattern is transferred onto a semiconductor wafer and used as the basis of the wafer pattern.

Another data conversion process, a process called OPC (Optical Proximity Correction) for correcting the OPE (Optical Proximity Effect) that occurs when exposing and transferring the mask pattern onto the semiconductor wafer by using the photomask and an exposure apparatus is performed.

As still another conversion process, a process called PPC (Process Proximity Correction) for correcting pattern deformation caused by the PPE (Process Proximity Effect) when processing the exposed wafer pattern by development and etching is performed.

As still other conversion processes, a wafer pattern dimension correction process called resizing and a negative-positive reversing process (white-black reversing process) of reversing negative and positive of the wafer pattern are performed. The dimension correction process and negative-positive reversing process are also collectively called an MDP (Mask Data Preparation) process.

The various processes as described above or the CAD process combining these processes is performed on the design data in step 2. On the basis of the design data having undergone the CAD process, data of the desired mask pattern to be formed on a photomask is formed.

Subsequently, the mask pattern data formed in step 2 is converted into mask write data. More specifically, the mask pattern data as pattern information (graphical information) is converted into mask write data (mask data) that can be input to, e.g., a pattern writing apparatus or pattern generator to be used to make a photomask. This step is step 3 (St.3). A representative example of the pattern writing apparatus or pattern generator is an electron beam lithography apparatus.

As shown in FIG. 1, step 4 (St.4) to be described below is executed in parallel when executing steps 2 and 3 described above.

First, pieces of information for a predetermined data conversion process are extracted as execution information of the CAD process in step 2. In addition, information of the data conversion process in step 2 is coded. A code pattern that contains the coded conversion information and manages information complying with the data conversion process when forming the photomask, such as the CAD process in step 2, is formed on the photomask. This step is step 4 (St.4). That is, the information complying with the data processing when forming the photomask is managed on the basis of the coded conversion information contained in the code pattern formed in step 4. Step 4 will be explained in more detail below.

First, pieces of information roughly classified into items (1) to (4) below are extracted in the form of character strings as the execution information of the series of CAD process steps including, e.g., the MDP process, OPC process, and PPC process described earlier.

(1) Management information for identifying the design data of the wafer pattern designed in step 1 is extracted. This design data management information is used as input data when executing the CAD process in step 2 as described previously. More specifically, this input data contains the pattern dimension and pattern layout of the design data, the functions of the pattern inside a semiconductor device, and the like. The design data management information is unique information such as the version number and file name of the wafer pattern design data.

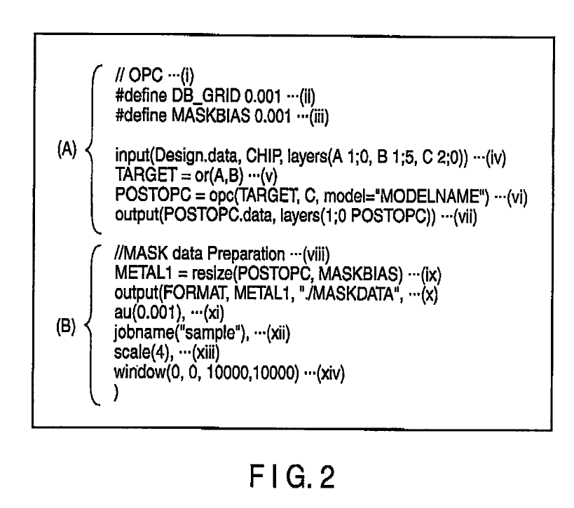

(2) Information (a procedure manual) concerning the procedure of the CAD process in step 2 is extracted. This CAD process procedure manual will be simply called a process deck in the following explanation. FIG. 2 shows an example of this process deck. The process deck shown in FIG. 2 is the extraction of process decks pertaining to the OPC process and MDP process from all process decks in step 2.

More specifically, of the process decks shown in FIG. 2, a process deck of seven lines (i) to (vii) starting from “//OPC” is process deck (A) concerning the OPC process. Also, a process deck of seven lines (viii) to (xiv) starting from “//MASK dataPreparation” following process deck (A) pertaining to the OPC process is process deck (B) concerning the MOP process.

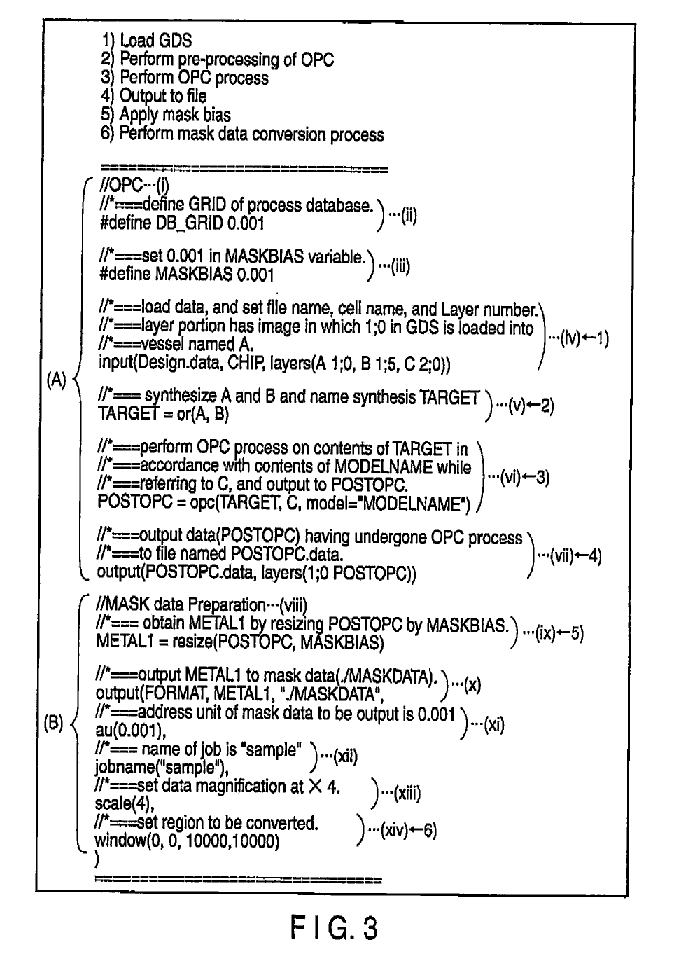

FIG. 3 shows more practical meanings and contents of descriptive expressions (i) to (xiv) of the process deck sample shown in FIG. 2. As indicated at the beginning of FIG. 3, the process deck sample shown in FIGS. 2 and 3 indicates the sequence of processes 1) to 6) below:

1) GDS (Global Drafting System) is loaded.

2) Pre-processing (ORing) of OPC is performed.

3) The OPC process is performed.

4) The data is output to a file.

5) A mask bias is applied.

6) The mask data conversion process is performed.

For example, process 1) above is equivalent to descriptive expression (iv) shown in FIGS. 2 and 3. Process 2) above is equivalent to descriptive expression (v). Process 3) above is equivalent to description expression (vi). Process 4) above is equivalent to descriptive expression (vii). Process 5) above is equivalent to descriptive expression (ix). Process 6) above is equivalent to descriptive expression (xiv).

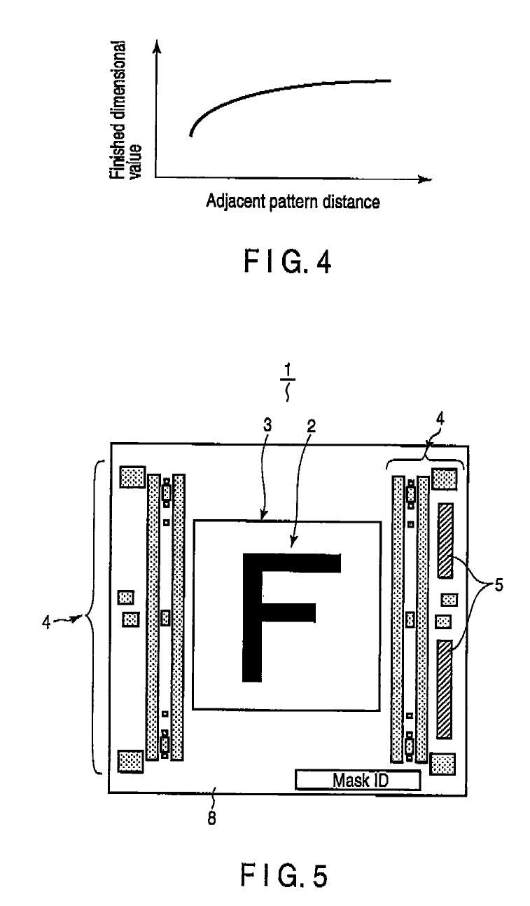

(3) Information for forming a correction model is extracted. FIG. 4 shows an example of this correction model formation information in the form of a graph. The abscissa of the graph shown in FIG. 4 represents the distance between a target pattern and an adjacent pattern closest to the target pattern. The ordinate of the graph shown in FIG. 4 represents the finished dimensional value of the target pattern on a wafer. More specifically, therefore, the graph shown in FIG. 4 represents the tendency of the change in finished dimensional value of the target pattern on a wafer as a function of the distance between the target pattern and adjacent pattern closest to the target pattern.

The wafer pattern correction model formation information shown in FIG. 4 can be obtained by, e.g., conducting a pattern transfer test beforehand on the basis of the design data formed in step 1 prior to the execution of step 4. That is, a mask pattern is first actually formed on a test photomask on the basis of the design data formed in step 1. Then, a wafer pattern is actually formed on a wafer by using the photomask having the mask pattern. After that, an error between the wafer pattern formed on the wafer and an ideal wafer pattern based on the design data formed in step 1 is measured. In this way, the water pattern correction model formation information shown in FIG. 4 can be obtained. Alternatively, it is also possible to similarly obtain the wafer pattern correction model formation information shown in FIG. 4 by performing simulation on the basis of the design data formed in step 1 before the execution of step 4.

Note that actual correction requires a more complicated correction model that is based on the correction model as shown in FIG. 4, and meets the allowable range of the fluctuation in finished dimensional value of the target pattern. That is, actual correction requires a correction model except for the correction model based on the distance between the target pattern and another pattern placed around the target pattern, e.g., the above-mentioned distance between the target pattern and its adjacent pattern. An example of the correction model is a dimension correction model containing a target pattern dimensional difference based on the pattern coverage in a peripheral region of the target pattern. Note that the wafer pattern correction model formation information shown in FIG. 4 is preferably information for forming a correction model for wafer pattern correction including not only the OPC process but also the PPC process.

(4) Data processing environment information is extracted. More specifically, this data processing environment information indicates management information for identifying a computer as a hardware system for executing the CAD process described above, and management information for identifying a software system for the CAD process. In particular, the management information for identifying the software system contains the name, version number, and the like of the software.

In step 4, the pieces of information roughly classified into items (1) to (4) explained above are extracted as character strings.

Subsequently, in step 4, to prevent information (1) to (4) from being easily interpreted by any third party, each information is processed into information encrypted by combining it with a predetermined keyword. In addition, the encrypted information is converted into a code pattern, e.g., a two-dimensional barcode pattern. Therefore, this two-dimensional barcode pattern contains, e.g., the information representing the data conversion system and data conversion method used in the data conversion process of converting the mask pattern data into the write data in step 3 described previously, and the data conversion process deck information expressing the procedure of the data conversion process. The two-dimensional barcode pattern also contains the information representing the OPC correction model described in item (3) above. Note that the two-dimensional barcode pattern is generated as data expression interpretable by a pattern writing apparatus, together with the mask write data converted from the mask pattern data in step 3 described earlier.

After that, a photomask having a desired mask pattern is made. More specifically, a desired mask pattern is formed on a photomask on the basis of the above-mentioned mask write data. In parallel with this processing, the aforesaid two-dimensional barcode pattern is formed in a region except for the region where the mask pattern of the photomask is to be formed. This step is step 5 (St.5). In this manner, the steps of forming the photomask according to this embodiment are completed.

FIG. 5 schematically shows the image of a photomask 1 formed by the steps as described above. Referring to FIG. 5, a region 3 having a black F mark 2 in the center of the photomask 1 is a region where a mask pattern serving as a desired semiconductor device pattern (wafer pattern) is to be formed. Assume that the F mark 2 is a representative mask pattern. A region 8 outside the region 3 in the plane of the photomask 1 is a region except for the mask pattern formation region. The boundary between the mask pattern formation region 3 and non-mask pattern formation region 8 is set as a range within which other patterns or marks (to be described later) are not transferred onto a wafer and the mask pattern 2 can be exposed and transferred with a proper shape in an actual pattern transfer step.

In the region 8 except for the mask pattern formation region, a plurality of dotted regions 4 shown in FIG. 5 are regions where patterns having functions different from that of the mask pattern 2 are to be formed. For example, alignment marks necessary to transfer the mask pattern 2 of the photomask 1 onto a semiconductor wafer by using an exposing means called an aligner are formed in the regions 4. Alternatively, QC (Quality Control) marks for monitoring the pattern accuracy independent of a semiconductor device pattern unique to each of a plurality of photomasks 1 are formed in the regions 4.

Also, a plurality of hatched regions 5 shown in FIG. 5 are regions where the two-dimensional barcode pattern described above is to be formed. The two-dimensional barcode pattern formed in the regions 5 contains not only the coded data conversion information and the management information of data processing complying with the formation of the photomask 1 described previously, but also information expressing pattern positional accuracy measurement information and positional accuracy suitability determination information. The information expressing the pattern positional accuracy measurement information and positional accuracy suitability determination information is, e.g., information concerning the pattern positional accuracy measured when performing alignment on the basis of the alignment marks, and information pertaining to whether the pattern positional accuracy falls within its allowable error range. As described above, the formation position of the two-dimensional barcode pattern is set in a position where the two-dimensional barcode is not transferred onto the wafer when the device pattern is exposed and transferred onto the wafer.

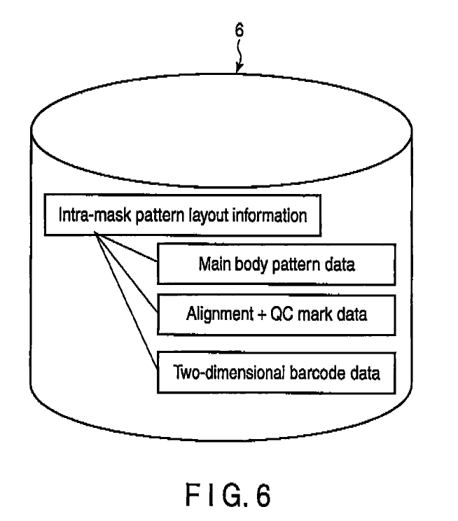

FIG. 6 exemplarily shows the system (structure) of the mask write data expressed by the patterns formed on each photomask 1. As shown in FIG. 6, a memory disk 6 separately contains pattern data of the wafer pattern main body expressing the semiconductor device pattern described above, data contained in the alignment marks and QC marks, and data contained in the two-dimensional barcode pattern. The memory disk 6 also contains intra-mask pattern layout information expressing the write position of each mark (each data) in the photomask 1. Data definition is performed by associating each data or each mark described above with the intra-mask pattern layout information.

Details of the aforesaid two-dimensional barcode pattern will be explained below.

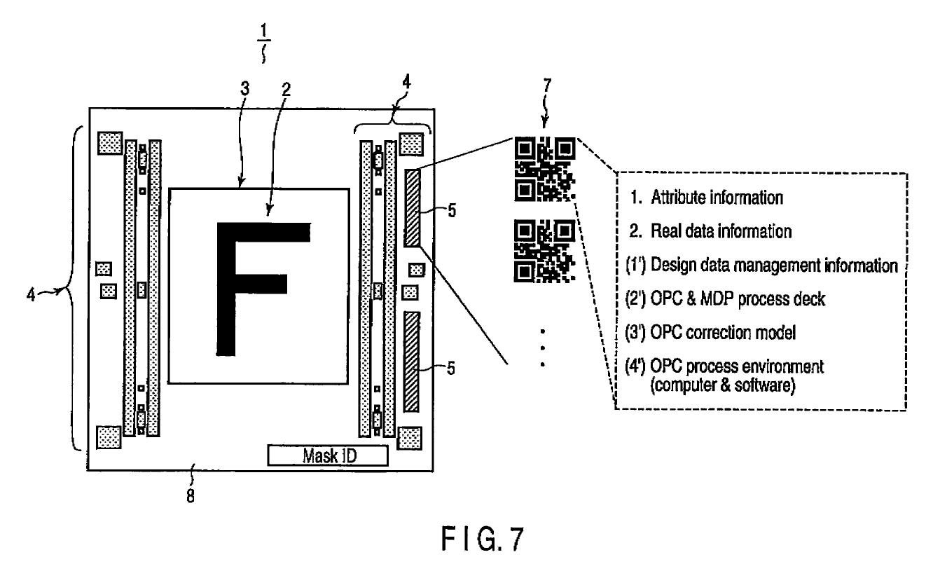

FIG. 7 schematically shows an example of information (data) expressed by the two-dimensional barcode pattern contained in the patterns formed on each photomask 1, and an example of the layout of the information. Referring to FIG. 7, two hatched regions 5 are set as regions where a two-dimensional barcode pattern 7 is to be formed, as in FIG. 5 described previously. Note that the number of characters expressible by one two-dimensional barcode pattern 7 is limited. Accordingly, a plurality of two-dimensional barcode patterns 7 are used as shown in FIG. 7 if the amount of information to be expressed by using the two-dimensional barcode pattern 7 is too large to be expressed by one two-dimensional barcode pattern 7, or if a plurality of pieces of information to be expressed by the two-dimensional barcode pattern 7 are different. For the amount or attribute of each information to be expressed by the two-dimensional barcode pattern 7, the information to be expressed by the two-dimensional barcode pattern 7 is individually defined. The two-dimensional barcode patterns 7 in which these pieces of information to be expressed are individually defined are laid out in a plurality of portions in the regions of the photomask 1 where the mask pattern 2 is not formed.

Note that the information attribute herein mentioned is identification information for discriminating between, e.g., the pattern positional accuracy measurement information and positional accuracy suitability determination information, as information to be expressed by the two-dimensional barcode pattern 7 as an object. Note also that even when certain information is expressed by a plurality of two-dimensional barcode patterns 7, the information is preferably classified and expressed on the basis of the attribute information.

More specifically, as shown in FIG. 7, each two-dimensional barcode pattern 7 contains, as “1. Attribute information”, attribute information representing the information attribute of execution information of the series of CAD process steps including, e.g., the MDP process, OPC process, and PPC process explained with reference to FIG. 1. In addition, each two-dimensional barcode pattern 7 contains, as “2. Real data information”, actual process information to be used when executing the above-mentioned CAD process. That is, to allow a data processor as a mask pattern formation apparatus such as a computer to read out the contents of pieces of information (1) to (4) formed in step 4 described earlier, pieces of information (1′) to (4′) respectively corresponding to pieces of information (1) to (4) are incorporated as execution data in each two-dimensional barcode pattern 7. This makes it possible to manage the CAD process step execution information of a formed photomask 1 by integrating the information with the photomask 1 having undergone the CAD process.

Accordingly, the first embodiment can facilitate information management by obtaining matching between the information (data) of the mask pattern 2 itself formed on the photomask 1, and various kinds of important information (data), except for the aforesaid information, to be used when forming the photomask 1. When making a large amount of photomasks 1, it is naturally possible to accurately and efficiently manage pieces of CAD process step execution information unique to individual photomasks 1 in one-to-one correspondence with the photomasks 1, such that each execution information is integrated with the photomask 1 having undergone the corresponding CAD process. Therefore, the above-mentioned high information managing capability obtained by this embodiment becomes notable as the number of photomasks 1 to be made increases.

In the first embodiment as has been explained above, design data for forming mask data required to form a photomask 1 for use in the fabrication of a semiconductor device and data processing information that expresses the procedures, tools, and process environments of various processes performed when converting the design data into the mask data and complies with the making of the photomask 1 are collectively generated as patterns for each photomask 1 to be processed. The generated patterned data and a mask pattern 2 serving as a semiconductor device pattern (wafer pattern) are collectively formed on the photomask 1. This makes it possible to manage the data (patterns) and the formed photomask 1 by integrating them. That is, in this embodiment, the data processing information that is related to the formation of a semiconductor device pattern and conventionally managed by using a document or a recording medium, such as a magnetic disk, different from the photomask 1 can be accurately, easily, and efficiently managed by integrating the information with the photomask 1 (mask pattern 2) as an intermediate product for forming the semiconductor device pattern on a semiconductor wafer.

This obviates the need for any infrastructure for managing the data processing information pertaining to the photomask 1 to be made. It is also possible to eliminate mismatching between the data processing information of the mask pattern 2 itself to be formed on the photomask 1 and the various kinds of data processing information pertaining to the making of the photomask 1. Accordingly, this embodiment can simplify the steps of managing the various information contents and data pertaining to the formation of the photomask 1, such as the information contents concerning the mask pattern 2 itself to be formed on the photomask 1, and reduce the labor required for the data management. Hence, the use of the photomask formation method according to this embodiment makes it possible to reduce the cost required for the fabrication and development of a semiconductor device.

### Second Embodiment

A photomask, photomask formation method, and semiconductor device fabrication method according to the second embodiment of the present invention will be briefly explained below although none of them is shown in any drawing. Note that the same reference numerals as in the first embodiment described above denote the same parts, and a repetitive explanation will be omitted.

The second embodiment is directed to a technique of fabricating a semiconductor device by using a photomask 1 formed by the photomask formation method according to the first embodiment.

First, a mask pattern 2 is exposed and transferred onto a resist film on a semiconductor wafer by using an exposure apparatus and the photomask 1. In addition, a resist pattern based on the mask pattern 2 is formed on the resist film by developing it. Subsequently, a film to be processed and semiconductor substrate below the resist film are processed by etching or the like along the resist pattern formed on the resist film. Consequently, a desired wafer pattern serving as a semiconductor device pattern can be formed on the semiconductor wafer. After that, the semiconductor wafer having the wafer pattern is supplied to, e.g., a transistor fabrication step, interconnection formation step, dicing step, chip mounting step, bonding step, and molding step. In this way, a desired semiconductor device (not shown) according to this embodiment is obtained.

In the second embodiment, as has been explained above, the mask pattern 2 is exposed and transferred by using the photomask 1 according to the first embodiment. This makes it possible to accurately, easily, and efficiently form a desired wafer pattern on a semiconductor wafer. Accordingly, the semiconductor device fabrication method according to this embodiment can accurately, easily, and efficiently fabricate a semiconductor device having a desired function, thereby reducing the cost, labor, or time required for the fabrication of the semiconductor device.

As described above, according to one aspect of this invention, it is possible to obtain a photomask, photomask formation method, and semiconductor device fabrication method capable of reducing the fabrication cost of a semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A photomask formation method comprising:
converting design data of a wafer pattern to be formed on a semiconductor wafer into mask data corresponding to a mask pattern to be formed on a photomask for use in the formation of the wafer pattern, and forming the mask pattern on the photomask on the basis of the mask data; and
forming, on the photomask, a code pattern obtained by coding information of the data conversion process of converting the design data into the mask data.

2. The method according to claim 1, further comprising performing a CAD (Computer Aided Design) process on the design data by a computer, before converting the design data into the mask data.

3. The method according to claim 2, wherein performing the CAD process includes at least one of an interlayer data calculation process, an optical proximity correction process, process proximity correction, an MDP (Mask Data Preparation) process, and a process of converting the design data into write data suitable for a pattern writing apparatus for use in the formation of the photomask.

4. The method according to claim 1, wherein when forming a desired mask pattern on the photomask on the basis of mask write data, the code pattern is formed in a region except for a region where the mask pattern of the photomask is to be formed.

5. The method according to claim 1, wherein the code pattern includes at least one of identification information for identifying the design data, information expressing a procedure of the data conversion process, information for forming a correction model for use in the data conversion process, information expressing an environment of the data conversion process, and information of a conversion process of converting the design data into write data suitable for a mask writing apparatus for use in the formation of the photomask.

6. The method according to claim 1, wherein the code pattern is a two-dimensional barcode pattern including encrypted information.

7. The method according to claim 6, wherein the two-dimensional barcode pattern includes at least one of information representing a data conversion system and a data conversion method for use in a data conversion process of converting mask pattern data into write data, data conversion process deck information expressing a procedure of the data conversion process, information representing an optical proximity correction model, pattern positional accuracy measurement information, and positional accuracy suitability determination information.

8. A photomask comprising a code pattern obtained by coding information of a data conversion process of converting design data of a wafer pattern to be formed on a semiconductor wafer into mask data corresponding to a mask pattern to be formed on a photomask for use in the formation of the wafer pattern.

9. The photomask according to claim 8, wherein the code pattern is formed in a region except for a region where the mask pattern of the photomask is to be formed.

10. The photomask according to claim 8, wherein the code pattern is a two-dimensional barcode pattern including encrypted information.

11. A semiconductor device fabrication method comprising:
transferring a mask pattern onto a semiconductor wafer by using a photomask; and
forming the wafer pattern on the semiconductor wafer on the basis of the transferred mask pattern,
a method of forming the photomask including
converting design data of a wafer pattern to be formed on a semiconductor wafer into mask data corresponding to a mask pattern to be formed on a photomask for use in the formation of the wafer pattern, and forming the mask pattern on the photomask on the basis of the mask data; and
forming, on the photomask, a code pattern obtained by coding information of the data conversion process of converting the design data into the mask data.

12. The method according to claim 11, further comprising performing a CAD (Computer Aided Design) process on the design data by a computer, before converting the design data into the mask data.

13. The method according to claim 12, wherein performing the CAD process includes at least one of an interlayer data calculation process, an optical proximity correction process, process proximity correction, an MDP (Mask Data Preparation) process, and a process of converting the design data into write data suitable for a pattern writing apparatus for use in the formation of the photomask.

14. The method according to claim 11, wherein when forming a desired mask pattern on the photomask on the basis of mask write data, the code pattern is formed in a region except for a region where the mask pattern of the photomask is to be formed.

15. The method according to claim 11, wherein the code pattern includes at least one of identification information for identifying the design data, information expressing a procedure of the data conversion process, information for forming a correction model for use in the data conversion process, information expressing an environment of the data conversion process, and information of a conversion process of converting the design data into write data suitable for a mask writing apparatus for use in the formation of the photomask.

16. The method according to claim 11, wherein the code pattern is a two-dimensional barcode pattern including encrypted information.

17. The method according to claim 16, wherein the two-dimensional barcode pattern includes at least one of information representing a data conversion system and a data conversion method for use in a data conversion process of converting mask pattern data into write data, data conversion process deck information expressing a procedure of the data conversion process, information representing an optical proximity correction model, pattern positional accuracy measurement information, and positional accuracy suitability determination information.
